(19) United States
(12) Patent Application Publication
(10) Pub. No.: US 2026/0047303 A1
(43) Pub. Date: Feb. 12, 2026

(54) DISPLAY DEVICE, METHOD OF MANUFACTURING THE SAME AND ELECTRONIC DEVICE INCLUDING THE SAME

(71) Applicant: Samsung Display Co., LTD., Yongin-si (KR)

(72) Inventors: Jae Hyuk JANG, Yongin-si (KR); Kang Woo KIM, Yongin-si (KR); Sang Ho KIM, Yongin-si (KR); Yong Jae JANG, Yongin-si (KR)

(73) Assignee: Samsung Display Co., LTD., Yongin-si (KR)

(21) Appl. No.: 19/072,437

(22) Filed: Mar. 6, 2025

(30) Foreign Application Priority Data
Aug. 6, 2024 (KR) 10-2024-0104831

(51) Int. Cl. H10K 59/38; H10K 59/12; H10K 59/122

(52) U.S. Cl. CPC H10K 59/38; H10K 59/1201; H10K 59/122

(57) ABSTRACT

A display device includes a lower structure including light-emitting devices, and an upper structure combined with the lower structure and facing the lower structure. The upper structure includes an upper substrate and color conversion columns on a surface of the upper substrate. Each of the color conversion columns includes a bank and color conversion layers in the bank. Each of the color conversion layer corresponds to each of the light-emitting devices. A trench extends between the color conversion columns and has at least one open end portion.

### CROSS-REFERENCE TO RELATED APPLICATION(S)

This application claims priority to and benefits of Korean Patent Application No. 10-2024-0104831 under 35 U.S. C. § 119, filed on Aug. 6, 2024 in the Korean Intellectual Property Office (KIPO), the entire contents of which are incorporated herein by reference.

### TECHNICAL FIELD

Embodiments relate to a display device, a method of manufacturing the display device and an electronic device including the display device. Specifically, embodiments relate to a display device including a color control structure, a method of manufacturing the display device and an electronic device including the display device.

### BACKGROUND

An organic light-emitting device may have self-luminous properties and provide improved viewing angles and contrast, as well as high response speed and high luminance. A display device may include multiple pixels that emit light in different colors. The pixels may include a color control portion, including, e.g., a quantum dot, to improve color purity.

Light of a first color generated by a light-emitting portion of a pixel may be converted into light of a second color as it passes through the color control portion and is emitted to an outside.

### SUMMARY

According to an aspect of embodiments, a display device is provided having improved mechanical properties and light-emitting reliability.

According to an aspect of embodiments, a method of manufacturing a display device is provided, offering improved mechanical properties and light-emitting reliability.

According to an aspect of embodiments, an electronic device is provided, including a display device having improved mechanical properties and light-emitting reliability.

A display device may include a lower structure including light-emitting devices, and an upper structure combined with the lower structure and facing the lower structure. The upper structure may include an upper substrate and color conversion columns on a surface of the upper substrate. Each of the color conversion columns may include a bank and color conversion layers in the bank. Each of the color conversion layers may correspond to each of the light-emitting devices. A trench may extend between the color conversion columns and have at least one open end portion.

In embodiments, the trench may be defined by sidewalls of the bank included in a pair of neighboring color conversion columns, and at least one end portion of the trench may remain unblocked by the bank.

In embodiments, end portions of the trench may be open.

In embodiments, the color conversion columns may be repeatedly arranged and physically separated from each other, with the trench disposed between the color conversion columns.

In embodiments, each of the trench and the color conversion columns may have a first end portion and a second end portion in an extension direction of the color conversion columns. One of the first and second end portions of the trench may be blocked and another one of the first and second end portions may be open.

In embodiments, the trench may include a first trench having the first end portion blocked and a second trench having the second end portion blocked.

In embodiments, the display device may further include a first column connection portion that blocks the first end portion of the first trench and connects the first end portions of neighboring color conversion columns, and a second column connection portion that blocks the second end portion of the second trench and connects the second end portions of the neighboring color conversion columns.

In embodiments, the first column connection portion and the second column connection portion may be repeated alternately along a direction intersecting the extension direction of the color conversion columns.

In embodiments, the color conversion columns may be connected to each other in a zigzag pattern.

In embodiments, the first column connection portion and the second column connection portion may include a same material as the banks included in the neighboring color conversion columns, and may be integrally connected to the banks.

In embodiments, three or more of the color conversion columns may be connected by the first column connection portion to form a first color conversion column group, and three or more of the color conversion columns may be connected by the second column connection portion to form a second color conversion column group.

In embodiments, the first color conversion column group and the second color conversion column group may be alternately repeated and share one color conversion column.

In embodiments, the trench may include a trench in which only one of end portions in an extension direction of the color conversion columns is open, and a trench in which end portions in the extension direction of the color conversion columns are open.

In embodiments, the trench may include a first trench having first end portion blocked in the extension direction of the color conversion columns, a second trench having second end portion blocked, and a third trench having first and second end portions open.

In embodiments, the display device may further include a filler layer disposed between the upper structure and the lower structure to fill the trench.

In embodiments, the light-emitting devices and the color conversion layers may overlap each other to define pixels, and the trench may be formed as a transparent area.

A display device may include a lower structure comprising light-emitting devices, and an upper structure combined with the lower structure and facing the lower structure. The upper structure may include an upper substrate, and color conversion columns on a surface of the upper substrate. Each of the color conversion columns may include a bank and color conversion layers in the bank. Each of the color conversion layers may correspond to each of the light-emitting devices. The color conversion columns may be repeatedly arranged at a specific interval along a first direction parallel to the surface, and each of the color conversion columns may extend in a second direction parallel to the surface and intersecting the first direction. First end portions or second end portions in the second direction of neighboring color conversion columns may be physically separated from each other in the first direction.

In embodiments, the display device may further include a first column connection portion that connects first end portions of neighboring color conversion columns and a second column connection portion that connects second end portions of the neighboring color conversion columns.

In a method of manufacturing a display device, a bank layer may be formed on a surface of an upper substrate. The bank layer may be partially removed to form a trench having at least one open end portion and color conversion holes surrounded by the bank layer. Color conversion layers may be formed in the color conversion holes. The trench may be filled with a filling material, which diffuses into the open end portion of the trench. A lower structure including light-emitting devices and the upper substrate, on which the bank layer and the color conversion layer are formed, may be combined using the filling material.

In embodiments, before forming the bank layer, color filters may be formed on a surface of the upper substrate. A passivation layer may be formed along the surface of the upper substrate and the surfaces of the color filters. The color conversion holes may expose portions of the passivation layer formed on top surfaces of the color filters.

An electronic device may include the above-described display device, a memory, and a processor that executes data included in the memory to control an operation of the display device.

In embodiments, the electronic device may include virtual reality glasses, augmented reality glasses, a smartphone, a tablet PC, a laptop, a TV, a desk monitor, smart glasses, a head mounted display, a smart watch, or a vehicle display.

A display device according to the embodiments may include a trench forming a transparent area between color conversion columns that includes a bank. At least one end portion of the trench may be open to improve a spreading property of a filling material and to prevent aggregation of the filling material at an end portion of the bank.

Thus, optical disturbances caused by diffuse reflection and light scattering at an aggregated portion of the filling material may be suppressed, thereby improving image quality.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic exploded perspective view illustrating a display device or an electronic device in accordance with embodiments.

FIG. 2 is a schematic cross-sectional view of a display panel in accordance with embodiments.

FIG. 3 is a schematic plan view illustrating a circuit structure of a display device in accordance with embodiments.

FIG. 4 is a schematic plan view illustrating a pixel arrangement of a display device in accordance with embodiments.

FIGS. 5 and 6 are schematic cross-sectional views illustrating a display device in accordance with embodiments.

FIGS. 7A and 7B are schematic cross-sectional views illustrating light-emitting devices in accordance with embodiments.

FIG. 8 is a schematic perspective view illustrating an upper structure of a display device in accordance with embodiments.

FIGS. 9 and 10 are a schematic plan view and a schematic perspective view, respectively, illustrating an upper structure of a display device in accordance with embodiments.

FIGS. 11 and 12 are schematic plan views illustrating an upper structure of a display device in accordance with embodiments.

FIGS. 13 to 17 are schematic cross-sectional views illustrating a method of manufacturing a display device in accordance with embodiments.

FIG. 18 is a schematic block diagram of an electronic device in accordance with an embodiment.

FIG. 19 is a schematic diagram of electronic devices in accordance with various embodiments.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art. Various embodiments do not have to be exclusive nor limit the disclosure. For example, specific shapes, configurations, and characteristics of an embodiment may be used or implemented in another embodiment.

In the drawings, sizes, thicknesses, ratios, and dimensions of the elements may be exaggerated for ease of description and for clarity. Like reference numbers and/or reference characters refer to like elements throughout

As used herein, the singular forms “a,” “an,” and “the” are intended to include the plural forms as well, unless the context clearly indicates otherwise.

As used herein, the term “about” or “approximately” is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the specification and claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or. ”

The phrase “in a plan view” means viewing the object from the top, and the phrase “in a schematic cross-sectional view” means viewing a cross-section of which the object is vertically cut from the side. Hence, the expression “in a plan view” used herein may mean that an object is viewed in the third z direction from the top. The phrase “in a schematic cross-sectional view” means viewing a cross-section in the first x direction or the second y direction of which the object is vertically cut from the side. The third z direction also can be referred to as a “thickness direction. ”

It will be understood that when an element (or a layer, a region, a portion, or the like) is referred to as “formed on,” “being on,” “disposed on,” “connected to,” or “coupled to” another element in the specification, it can be directly formed on, disposed on, connected or coupled to another element mentioned above, or intervening elements may be disposed therebetween. It will be understood that the terms “connected to” or “coupled to” may include a physical or electrical connection or coupling.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z

The term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or. ”

It will be understood that, although the terms “first,” “second,” etc. may be used herein to describe various elements, these elements should not be limited by these terms. These terms are only used to distinguish one element from another. For example, a first element may be referred to as a second element, and similarly, a second element may be referred to as a first element without departing from the scope of the disclosure.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

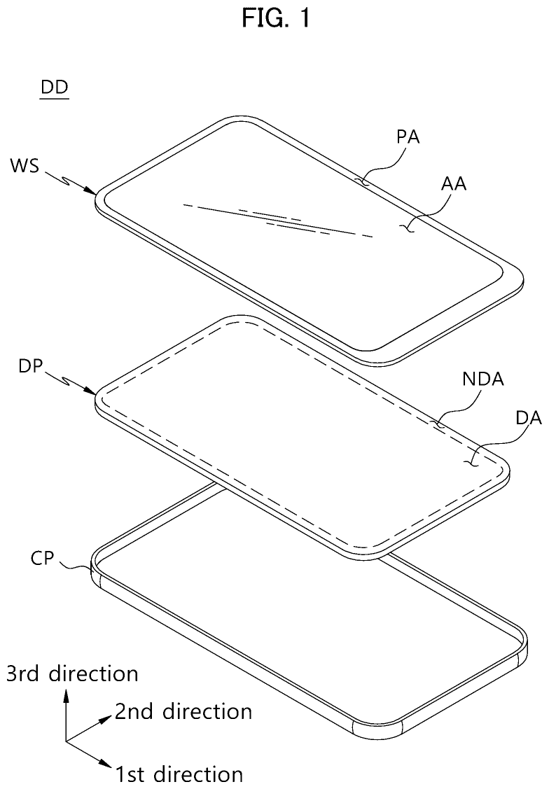

FIG. 1 is a schematic exploded perspective view illustrating a display device or an electronic device in accordance with embodiments.

Referring to FIG. 1, a display device DD or an electronic device including the display device may include a window structure WS, a display panel DP, and a cover panel CP. The display device DD may include a liquid crystal display (LCD) device, an organic light emitting diode (OLED) display, a quantum dot light emitting diode (QLED) display, etc.

In embodiments, the display device DD may include a quantum dot (QD)-organic light emitting diode (OLED) display device.

In FIG. 1, a first direction and a second direction may refer to two directions that are parallel to and intersect a display surface of the window structure WS and/or the display panel DP. For example, the first direction and the second direction may be orthogonal to each other.

For example, the first direction may correspond to an X-direction (a row direction) of the display device DD or the display panel DP, and the second direction may correspond to a Y-direction (a column direction) of the display device DD or the display panel DP.

A third direction may be perpendicular to the first direction and the second direction. The third direction may correspond to a Z-direction (a thickness direction) of the display device DD or the display panel DP.

In the accompanying drawings, the definition of the direction described above may apply equally.

The cover panel CP, the display panel DP, and the window structure WS may be sequentially stacked in the third direction.

The window structure WS may provide an external display surface recognized by a user of the display device DD or the electronic device, and may include a transparent film. For example, the window structure WS may include glass (e.g., ultra-thin glass UTG), a hard coating film, a plastic film, etc.

An outer surface of the window structure WS may include an active area AA and a peripheral area PA. The active area AA may provide a surface from which an image of the display device DD is substantially displayed and to which a user's touch or command is input. The peripheral area PA may substantially correspond to a bezel area of the display device DD.

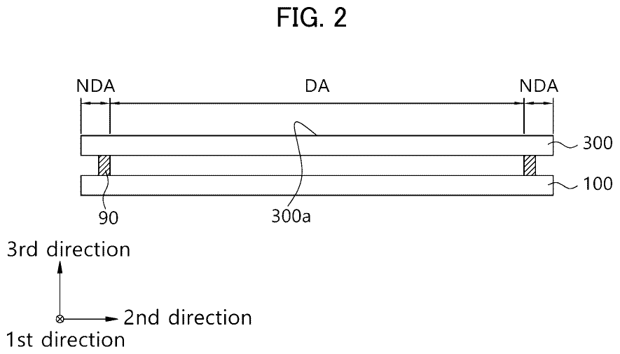

In embodiments, an upper substrate 300 (see FIG. 2) may function as a window structure WS.

The display panel DP may include a display area DA and a non-display area NDA. The display area DA of the display panel DP may substantially correspond to or overlap the active area AA of the window structure WS. The non-display area NDA of the display panel DP may substantially correspond to or overlap the peripheral area PA of the window structure WS.

The cover panel CP may function as a rear panel or a housing (e.g., a rear housing) of the display device DD or the electronic device. The cover panel CP may include a plate (e.g., an SUS plate) that supports the display panel DP, a circuit board (PCB), etc. The cover panel CP may include an elastic body to absorb shock to the display device DD or the electronic device.

FIG. 2 is a schematic cross-sectional view of a display panel according to embodiments.

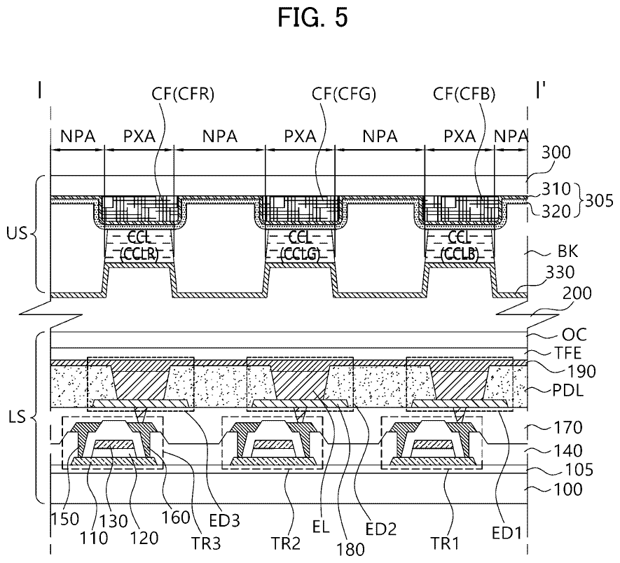

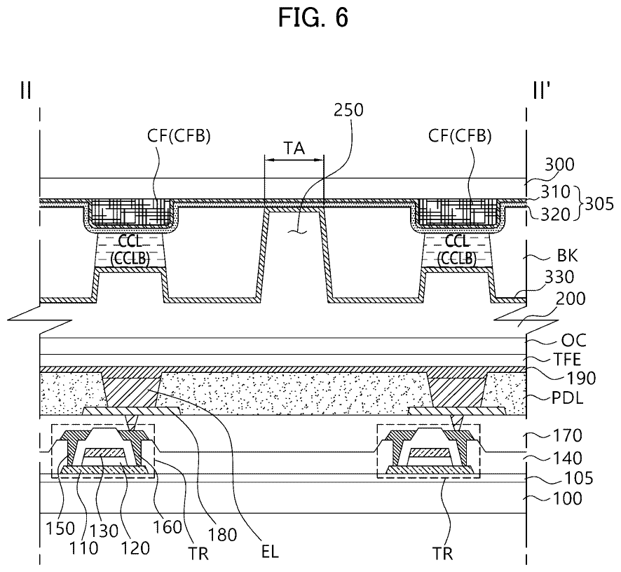

Referring to FIG. 2, the display panel DP or the display device DD may include an upper structure US and a lower structure LS. As described later with reference to FIGS. 5 and 6, the upper structure US may include an upper substrate 300 and a color control structure disposed on the upper substrate 300. The lower structure LS may include a lower substrate 100 and a light-emitting device disposed on the lower substrate 100.

In embodiments, the upper structure US and the lower structure LS may be coupled or laminated together using a sealant 90. An active surface or a display surface of the display device DD or the display panel DP may be provided by an outer surface 300a (e.g., a top surface of the upper substrate 300).

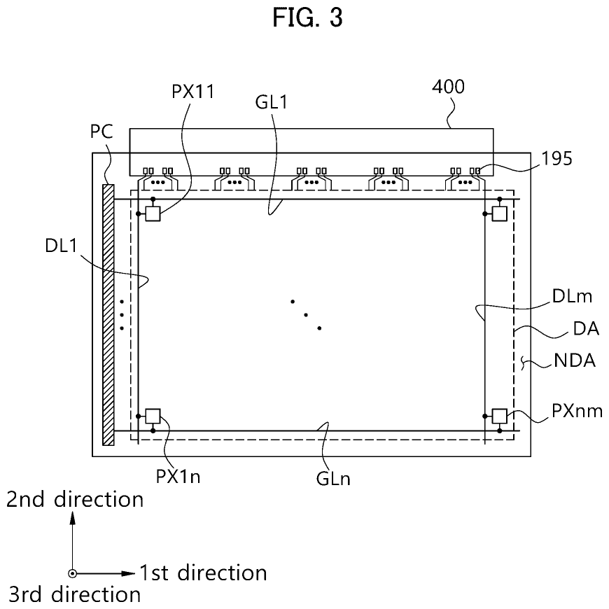

FIG. 3 is a schematic plan view illustrating a circuit structure of a display device in accordance with embodiments.

Referring to FIG. 3, multiple pixels PX11 to PXnm may be arranged in the display area DA of the display panel DP.

In embodiments, a pixel circuit in the lower structure LS of the display panel DP may include gate lines GL1 to GLn forming first to n^{th} rows and data lines DL1 to DLm forming first to m^{th} columns. Each of the pixels PX11 to PXnm may be connected to a corresponding n^{th} row gate line among the gate lines GL1 to GLn and a corresponding m^{th} column data line among the data lines DL1 to DLm.

Each of the pixels PX11 to PXnm may further include a pixel driving device (or pixel switching device) that includes a transistor and a light-emitting device, as described below. Although not illustrated in detail in FIG. 3, the pixel circuit may further include wirings, such as power lines, ground lines, etc.

FIG. 3 illustrates that the data lines DL1 to DLm extend in the second direction and the gate lines GL1 to GLn extend in the first direction, but the construction of the data lines and the gate lines is not limited to that illustrated in FIG. 3.

A peripheral circuit PC may be disposed in the peripheral area PA of the display device DD or the non-display area NDA of the display panel DP. For example, the peripheral circuit PC may include a gate driving circuit. The gate driving circuit may be integrated into the display panel DP using an oxide silicon gate driver circuit (OSG) process or an amorphous silicon gate driver circuit (ASG) process.

The display device DD may further include a printed circuit board 400. Pads 195 of the pixel circuit may be assembled at one end portion of the non-display area NDA. The printed circuit board 400 may be electrically connected to the pixel circuit through the pads 195. For example, the printed circuit board 400 may be electrically connected to the pads 195 using a heating-compression process with a conductive intermediate structure, such as an anisotropic conductive film (ACF).

An integrated circuit (IC), such as a data driving circuit, may be disposed on the printed circuit board 400. In embodiments, an integrated circuit (IC) chip in the form of a chip-on-film (COF) may be mounted on the printed circuit board 400.

FIG. 3 illustrates that each pixel PX11, PX1n to PXnm has a square shape for convenience of illustration, but the pixel shape is not limited thereto.

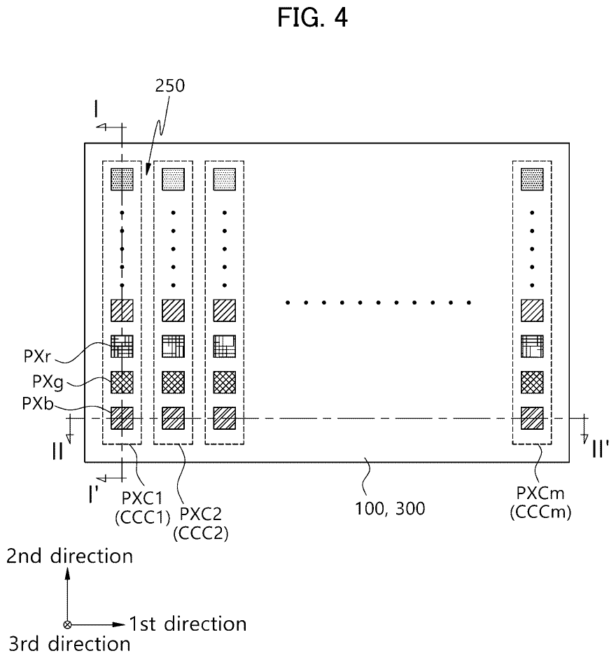

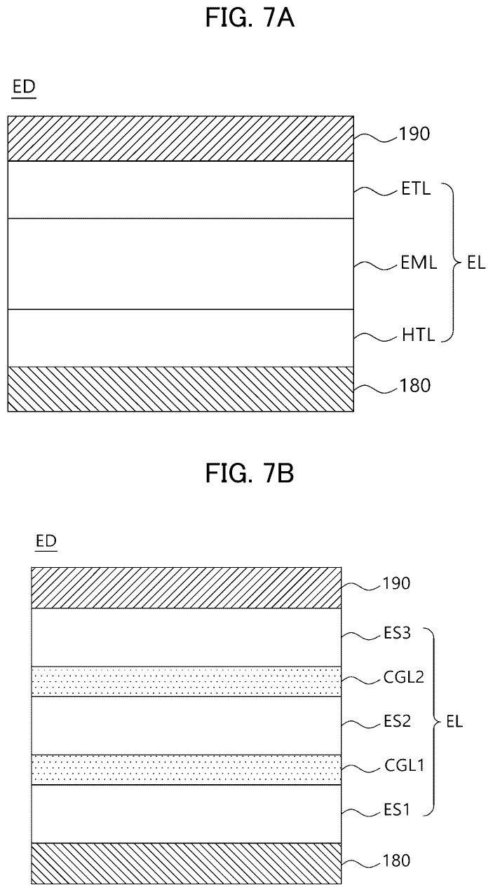

FIG. 4 is a schematic plan view illustrating a pixel arrangement in a display device in accordance with embodiments. FIGS. 5 and 6 are schematic cross-sectional views illustrating a display device in accordance with embodiments. FIGS. 7A and 7B are schematic cross-sectional views illustrating a light-emitting device in accordance with embodiments.

FIG. 5 is a schematic cross-sectional view taken along line I-I′ of FIG. 4 in the thickness direction. FIG. 6 is a schematic cross-sectional view taken along line II-II′ of FIG. 4 in the thickness direction.

Referring to FIGS. 4 to 6, pixels of the display device DD may include a first pixel PXb, a second pixel PXg, and a third pixel PXr. The first to third pixels PXb, PXg, and PXr may correspond to different colors.

In embodiments, the first pixel PXb may be a region emitting a blue light. For example, the first pixel PXb may be a region emitting a blue light having a central wavelength in a range from about 420 nm to about 480 nm. The second pixel PXg may be a region emitting a green light. For example, the second pixel PXg may be a region emitting a green light having a central wavelength in a range from about 500 nm to about 580 nm. The third pixel PXr may be a region emitting a red light. For example, the third pixel PXr may be a region emitting a red light having a central wavelength in a range from about 600 nm to about 670 nm.

FIG. 4 illustrates that the first pixel PXb, the second pixel PXg, and the third pixel PXr are sequentially arranged along the second direction, but an arrangement order of the pixels is not limited thereto.

A pixel group, as illustrated in FIG. 4, may be defined by the first pixel PXb, the second pixel PXg, and the third pixel PXr. The pixel group may be repeatedly arranged along the first direction and the second direction.

In embodiments, the pixel group may be repeatedly arranged along the second direction to form a pixel column PXC. Multiple pixel columns PXC may be repeatedly arranged along the first direction. For example, a first pixel column PXC1 to a m^{th} pixel column PXCm may be sequentially arranged along the first direction.

Each pixel column PXC may include a color conversion column CCC. The color conversion column CCC may include a bank BK extending in the second direction and color conversion layers CCL defined by the bank BK. A first color conversion column CCC1 to an m^{th} color conversion column CCCm may correspond to the first pixel column PXC1 to the m^{th} pixel column PXCm, respectively.

As described above, the upper structure US and the lower structure LS may be combined to form the display panel DP. The lower structure LS may include transistors TR1, TR2, and TR3 and a light-emitting portion EL. The upper structure US may include the color conversion layer CCL and a color filter CF. A color control structure for each pixel may be defined by the color conversion layer CCL and the color filter CF.

The lower structure LS may include a lower substrate 100, transistors TR1, TR2, and TR3 arranged on the lower substrate 100, and a light-emitting device ED connected to the transistors TR1, TR2, and TR3.

The lower substrate 100 may function as a base substrate of the display device DD or the display panel DP, or may function as a back-plane substrate. The lower substrate 100 may include a glass substrate, a ceramic substrate, or a plastic substrate. In embodiments, the lower substrate 100 may include a polymer material having transparency and flexibility. The lower substrate 100 may be employed in a transparent, flexible, bendable, or foldable display device.

For example, the lower substrate 100 may include a polymer material such as polyimide, polysiloxane, an epoxy resin, an acrylic resin, polyester, polyarylate, polycarbonate, polyethersulfone, polyphenylene sulfide, etc. In an embodiment, the lower substrate 100 may include polyimide.

A buffer layer 105 may be formed on a top surface of the lower substrate 100. The buffer layer 105 may block moisture from penetrating through the lower substrate 100 and prevent the diffusion of impurities between the lower substrate 100 and structures formed on the lower substrate 100. The buffer layer 105 may be formed entirely over the pixel area PXA and the non-pixel area NPA of the lower substrate 100, and may entirely cover the top surface of the lower substrate 100.

The buffer layer 105 may include an inorganic insulating material, such as silicon oxide, silicon nitride, silicon oxynitride, etc. These materials may be used alone or in combination. In embodiments, the buffer layer 105 may have a stacked structure including a silicon oxide layer and a silicon nitride layer.

The buffer layer 105 may be formed using a deposition process, such as a chemical vapor deposition (CVD) process, a sputtering process, or an atomic layer deposition (ALD) process, to include the inorganic insulating material.

The transistors TR1, TR2, and TR3 may be disposed on the buffer layer 105. The first transistor TR1, the second transistor TR2, and the third transistor TR3 may be electrically connected to the first light-emitting device ED1, the second light-emitting device ED2, and the third light-emitting device ED3, respectively.

Each of the transistors TR1, TR2, and TR3 may include an active layer 110, a gate insulation layer 120, a gate electrode 130, and connection electrodes 150 and 160. The transistors TR1, TR2, and TR3 may be electrically connected to the light-emitting device ED of the first pixel PXb, the second pixel PXg, and the third pixel PXr, respectively.

The active layer 110 may be disposed on the buffer layer 105 and may be patterned, for example, using a photo-lithography process to be repeatedly/regularly arranged for each pixel. The active layer 110 may include a silicon compound, such as polysilicon or an amorphous silicon. The active layer 110 may include a source region, a drain region, and a channel region, and p-type dopant or an n-type dopant may be introduced in some regions.

The active layer 110 may include an oxide semiconductor, such as indium gallium zinc oxide (IGZO), zinc tin oxide (ZTO), or indium tin zinc oxide (ITZO).

The gate insulation layer 120 may be formed on the active layer 110, and the gate electrode 130 may be stacked on the gate insulation layer 120. As illustrated in FIGS. 5 and 6, the gate insulation layer 120 may partially cover each active layer 110 in a patterned shape.

In other embodiments, the gate insulation layer 120 may extend continuously across multiple pixel areas PXA and may be shared by the first, second, and third transistors TR1, TR2, and TR3.

The gate electrode 130 may overlap the channel region of the active layer 110 along the third direction.

The gate insulation layer 120 may be formed using the deposition process described above and may include an inorganic insulating material, such as silicon oxide, silicon nitride, silicon oxynitride, etc. In embodiments, as illustrated in FIG. 5, the gate insulation layer 120 having a patterned shape may be formed through a photo-lithography process, using the gate electrode 130 substantially as an etching mask.

In embodiments, the gate electrode 130 and the gate insulation layer 120 may be used as an ion implantation mask for forming the source region and the drain region in the active layer 110.

An insulating interlayer 140, covering the gate insulation layer 120 and the gate electrode 130, may be formed on the active layer 110. The connection electrodes 150 and 160, which are in contact with or electrically connected to the active layer 110, may be formed on the insulating interlayer 140.

The insulating interlayer 140 may be formed using the deposition process described above and may include an inorganic insulating material, such as silicon oxide, silicon nitride, or silicon oxynitride. The insulating interlayer 140 may have a single-layered structure or a multi-layered structure including different materials.

In embodiments, in case that the active layer 110 includes an oxide semiconductor, hydrogen (H) from the insulating interlayer 140 may be diffused or moved into the active layer 110 during a heat treatment process in forming the insulating interlayer 140. Accordingly, a carrier concentration may be increased by hydrogen, and thus the source region and the drain region having increased conductivity may be formed at lateral portions of the active layer 110.

The connection electrodes 150 and 160 may penetrate the insulating interlayer 140 to connect with the active layer 110. In case that the gate insulation layer 120 is continuously formed commonly across multiple pixel regions, the connection electrodes 150 and 160 may also penetrate the gate insulation layer 120.

The connection electrodes 150 and 160 may include a source electrode 150, which is connected to or in contact with the source region of the active layer 110, and a drain electrode 160, which is connected to or in contact with the drain region of the active layer 110.

Contact holes may be formed by partially etching the insulating interlayer 140. For example, the contact hole exposing each of the source region and the drain region may be formed. A metal layer filling the contact holes may be formed on the insulating interlayer 140, and the metal layer may be partially etched to form the source electrode 150 and the drain electrode 160.

The gate electrode 130 and the connection electrodes 150 and 160 may include a metal such as Ag, Mg, Al, W, Cu, Ni, Cr, Mo, Ti, Pt, Ta, Nd, Sc, or an alloy or nitride thereof. The gate electrode 130 and the connection electrodes 150 and 160 may be formed using the deposition process described above.

A planarization layer 170, covering the connection electrodes 150 and 160, may be formed on the insulating interlayer 140. The planarization layer 170 may accommodate a via structure that electrically connects a pixel electrode 180 and the drain electrode 160.

In embodiments, the planarization layer 170 may include an organic material, such as polyimide, an epoxy resin, an acrylic resin, a polyester, a siloxane resin, a benzocyclobutene (BCB), or the like. The planarization layer 170 may be formed using the deposition process described above or a spin coating process.

The pixel electrode 180 may be formed in each pixel to be electrically connected to the transistors TR1, TR2, and TR3. The pixel electrode 180 may be formed on the planarization layer 170 and electrically connected to the drain electrode 160.

For example, the planarization layer 170 may be partially etched to form a via hole exposing a top surface of the drain electrode 160. A conductive layer, including a metal or a transparent conductive oxide and filling the via hole, may be formed on a top surface of the planarization layer 170, and the conductive layer may be partially etched to form the pixel electrode 180.

The pixel electrode 180 may serve as an anode and may include a high work function conductive material to promote hole injection. The pixel electrode 180 may function as a transmissive electrode. The pixel electrode 180 may include a transparent conductive oxide, such as indium tin oxide (ITO), indium zinc oxide (IZO), zinc oxide (ZnO), or indium tin zinc oxide (ITZO).

The pixel electrode 180 may function as a transflective electrode or a reflective electrode. The pixel electrode 180 may include a metal selected from Ag, Mg, Cu, Al, Pt, Pd, Au, Ni, Nd, Ir, Cr, Li, Ca, LiF, Mo, Ti, W, In, Sn, and Zn, or an alloy of two or more therefrom.

The pixel electrode 180 may have a single-layered structure or a multi-layered structure. For example, the pixel electrode 180 may have a triple-layered structure of ITO/Ag/ITO.

A pixel defining layer PDL exposing a top surface of the pixel electrode 180 may be formed on the planarization layer 170. The pixel defining layer PDL may define a light-emitting region through a sidewall of the pixel defining layer PDL. A red light-emitting region, a green light-emitting region, and a blue light-emitting region may be separated and defined by the pixel defining layer PDL, and the light-emitting devices ED1, ED2, and ED3 may correspond to a red light-emitting device, a green light-emitting device, and a blue light-emitting device, respectively.

In embodiments, all of the light-emitting device ED1, ED2, and ED3 may be white light-emitting devices or blue light-emitting devices.

The pixel defining layer PDL may be formed by coating a photosensitive organic material, such as a polysiloxane resin, a polyimide resin, or an acrylic resin, and by exposure and development processes. In embodiments, the pixel defining layer PDL may be formed using a printing process, such as an inkjet printing process, with a polymer material or an inorganic material.

The light-emitting portion EL may be disposed in each light-emitting region defined by the pixel defining layer PDL. In embodiments, the light-emitting portion EL may include an emission layer including an organic light-emitting material. For example, the light-emitting portion EL may be formed using a process such as a vacuum deposition, a spin coating, an inkjet printing, a laser printing, a casting, a laser thermal transfer, or the like.

A counter electrode 190 may be disposed on top surfaces of the pixel defining layer PDL and the light emitting-portion EL. The counter electrode 190 may function as a common electrode, extending continuously across multiple light emitting-regions or the pixels.

The counter electrode 190 may function as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These materials may be used alone or in combination of two or more therefrom.

The counter electrode 190 may function as a transmissive electrode, a transflective electrode, or a reflective electrode. The counter electrode 190 may have either a single-layered structure or a multi-layered structure.

The light-emitting device ED1, ED2, and ED3 may be defined by the pixel electrode 180, the light-emitting portion EL, and the counter electrode 190. The light-emitting device ED1, ED2, and ED3 may be provided as an organic light-emitting diode (OLED) device. Configurations and structures of the light-emitting portion EL and the light-emitting devices ED1, ED2, and ED3 will be described in more detail with reference to FIGS. 7A and 7B.

An encapsulation layer TFE may be formed on the counter electrode 190. The encapsulation layer TFE may be disposed on or cover the pixel defining layer PDL and the light-emitting devices ED1, ED2, and ED3 to protect the light-emitting devices ED1, ED2, and ED3 from moisture or oxygen.

The encapsulation layer TFE may include an inorganic layer, including silicon nitride (SiNₓ), silicon oxide (SiOₓ), indium tin oxide, indium zinc oxide, or any combination thereof; an organic layer, including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE), or any combination thereof; or a combination of the inorganic and organic layers.

The encapsulation layer TFE may have a single-layered structure or a multi-layered structure. In embodiments, the encapsulation layer TFE may have a sequentially stacked structure, including a first encapsulation layer, an organic layer, and a second inorganic layer.

An overcoating layer OC may be disposed on the encapsulation layer TFE. The overcoating layer OC may serve as a sealing or a device planarization layer for the lower structure LS. The overcoating layer OC may include a resin material, such as an acrylic resin, an epoxy resin, or an imide resin. For example, monomers of the resin may be coated on the encapsulation layer TFE, and the overcoating layer OC may be formed by a photo-curing.

In an embodiment, the overcoating layer OC may be omitted or merged with, or integrated into the encapsulation layer TFE.

As described above, the upper structure US may include the upper substrate 300 and the color control structure, which includes the color filter CF and the color conversion layer CCL stacked on the upper substrate 300. The color control structure substantially overlaps the light-emitting portion EL and may define the pixel area PXA or each of the individual pixels PXb, PXg, and PXr.

The color filter CF may be disposed on a bottom surface of the upper substrate 300 (a surface opposite the lower substrate 100 or a surface opposite the outer surface 300a of the upper substrate 300). The color filter CF may overlap the color conversion layer CCL of a corresponding pixel in the third direction.

The color filter CF may include a first color filter CFB, a second color filter CFG, and a third color filter CFR, which correspond to or overlap a first color conversion layer CCLB, a second color conversion layer CCLG, and a third color conversion layer CCLR, respectively.

The color filter CF may selectively transmit light in a specific wavelength band and may substantially absorb a remaining light. Accordingly, a color purity of the display device DD may be enhanced, and reflection of an external light may be decreased.

The first color filter CFB may transmit blue light having a central wavelength in a range, for example, from about 420 nm to about 480 nm. The second color filter CFG may transmit green light having a central wavelength in a range, for example, from about 500 nm to about 580 nm. The third color filter CFR may transmit red light having a central wavelength in a range, for example, from about 600 nm to about 670 nm.

Each of the color filters CFs may include a photosensitive binder resin and a colorant, which includes a pigment and/or dye. The first color filter CFB may include a blue pigment and/or a blue dye. The second color filter CFG may include a green pigment and/or a green dye. The third color filter CFR may include a red pigment and/or a red dye.

In embodiments, a passivation layer 305 covering the color filters CF may be formed on the bottom surface of the upper substrate 300. In embodiments, the passivation layer 305 may include a first passivation layer 310 and a second passivation layer 320.

The first passivation layer 310 may conformally cover the bottom surface of the upper substrate 300 and surfaces of the color filters CFs. In an embodiment, the first passivation layer 310 may directly contact both the bottom surface of the upper substrate 300 and the surfaces of the color filters CF.

The first passivation layer 310 may be formed of a low refractive index material having a refractive index difference of about 0.1 or more compared to a refractive index of the color filter CF and/or the color conversion layer CCL. For example, the first passivation layer 310 may include porous inorganic particles, such as silica (SiO₂), titania (TiO₂), zirconia (ZrO₂), or the like. Accordingly, a refractive index of the first passivation layer 310 may be effectively reduced.

The second passivation layer 320 may be stacked on top of the first passivation layer 310. The second passivation layer 320 may include an inorganic insulating material, such as silicon oxide, silicon nitride, aluminum oxide, and/or an organic insulating material.

In embodiments, the first passivation layer 310 and the second passivation layer 320 may function as a first low refractive index layer and a second low refractive index layer, respectively.

The bank BK may extend in the second direction and may include a hole (a color conversion hole CH (see FIG. 14) in which the color conversion layer CCL is formed. The color conversion layer CCL may fill the hole and may overlap both the color filter CF and the light-emitting portion EL of the corresponding pixel. The color conversion layer CCL may be disposed between the color filter CF and the light-emitting portion EL, while partially filling the hole.

The passivation layer 305 may be disposed between the color conversion layer CCL and the color filter CF.

For example, the bank BK may include a polymer resin material or a photoresist material and may be formed through a photo-lithography process, including exposure and development steps.

The color conversion layer CCL may include the first color conversion layer CCLB, the second color conversion layer CCLG, and the third color conversion layer CCLR, each corresponding to and overlapping the first light-emitting device ED1, the second light-emitting device ED2, and the third light-emitting device ED3, respectively, in the third direction.

The color conversion layer CCL may include quantum dots. The quantum dots may include a group II-VI compound, a group III-VI compound, a group I-III-VI compound, a group III-V compound, a group III-II-V compound, a group IV-VI compound, a group IV element or compound, or a combination thereof.

The quantum dot may include a core including the above-described compound and a shell surrounding the core. The shell may include an inorganic oxide or a semiconductor compound. The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like.

For example, a color of an emitted light may be controlled depending on a particle size of the quantum dot. The quantum dot may be classified as a blue quantum dot, a red quantum dot, a green quantum, or the like.

In embodiments, a blue light having a central wavelength in a range, for example, from about 420 nm to about 480 nm may be generated by the light-emitting portion EL. The first color conversion layer CCLB, corresponding to the first light-emitting device ED1 and the first pixel PXb, may transmit the blue light. The first color conversion layer CCLB may not include quantum dot but may include a scattering material. The scattering material may include TiO₂, ZnO, Al₂O₃, SiO₂, hollow silica, or the like. These materials may be used alone or in combinations of two or more therefrom.

The second color conversion layer CCLG, corresponding to the second light-emitting device ED2 and the second pixel PXg, may convert blue light into green light having a central wavelength in a range, for example, from about 500 nm to about 580 nm.

The third color conversion layer CCLR, corresponding to the third light-emitting device ED3 and the third pixel PXr, may convert blue light into red light having a central wavelength in a range, for example, from about 600 nm to about 670 nm.

The color conversion layers CCLB, CCLG, and CCLR may further include a binder resin to disperse the quantum dots and/or the scattering material. The binder resin may include an acrylic resin, a urethane resin, a silicon-based resin, an epoxy resin, or the like.

A capping layer 330 may be formed along surfaces of the bank BK and the color conversion layers CCL. The capping layer 330 may function as a protective layer of the color conversion layer CCL and as a low refractive index layer (e.g., a third low refractive index layer). For example, the capping layer 330 may be formed using an inorganic insulating material, such as silicon oxide, silicon nitride, aluminum oxide, or the like, and/or an organic insulating material, thereby ensuring a refractive index difference of about 0.1 or more from the color conversion layer CCL.

The color conversion layer CCL may be protected by the capping layer 330, which also enhances light-emitting efficiency and light recycling through reflection at an interface with the color conversion layer CCL. The capping layer 330 may cover an entire bottom surface of the color conversion layer CCL.

The upper structure US and the lower structure LS may be laminated or combined using a filler layer 200. The filler layer 200 may include a photocurable resin composition, such as an epoxy resin, an acrylic resin, and/or an imide resin.

In embodiments, as illustrated in FIGS. 4 and 6, a trench 250 may be formed between adjacent color conversion columns CCC.

The trench 250 may extend in the second direction and define the transparent area TA. Accordingly, the trench 250 may enable the implementation of a transparent display (e.g., a transparent OLED display or a transparent QD-OLED display) device.

The trench 250 may be defined as a space, and extend in the second direction from which the bank BK has been removed. The trench 250 may be defined or bordered by sidewalls of the bank BK included in the neighboring or adjacent color conversion columns CCC. A bottom surface of the trench 250 may be defined by (or correspond to) a bottom surface of the upper substrate 300 or a bottom surface of the passivation layer 305 exposed by the trench 250.

In embodiments, the capping layer 330 may be continuously formed along surfaces of the banks BK, the color conversion layers CCL, and the sidewalls and bottom surface of the trench 250.

According to embodiments, at least one end portion of both end portions of the trench 250 in the second direction may be open. In embodiments, as illustrated in FIG. 4, both end portions of the trench 250 may remain open without being blocked by the bank BK.

The filler layer 200 may fill the trenches 250 to combine the upper structure US and the lower structure LS with each other. As described below, the open end portion(s) of the trench 250 may enhance dispersion and flatness of the filler layer 200.

FIGS. 7A and 7B are schematic cross-sectional views illustrating light-emitting devices in accordance with embodiments.

Referring to FIGS. 7A and 7B, the light-emitting device ED may include a light-emitting portion EL disposed between the pixel electrode 180 and the counter electrode 190.

As illustrated in FIG. 7A, the light-emitting portion EL may include a hole transport layer HTL, an emission layer EML, and an electron transport layer ETL. In embodiments, the hole transport layer HTL, the emission layer EML, the electron transport layer ETL, and the counter electrode 190 may be sequentially stacked on a top surface of the pixel electrode 180.

The emission layer EML may include an organic light-emitting material. For example, the emission layer EML may include a fluorescent host and/or a phosphorescent host. The emission layer EML may further include a fluorescent dopant, a phosphorescent dopant, and/or a thermally activated delayed fluorescence (TADF) dopant.

For example, the hole transport layer HTL may include a hole transport material, such as m-MTDATA (4,4′,4″-[tris(3-methylphenyl)phenylamino] triphenylamine), TDATA (4,4′,4″-tris(N, N-diphenylamino)triphenylamine), 2-TNATA(4,4′,4″-tris[N(2-naphthyl)-N-phenylamino]-triphenylamine), NPB (N,N′-di(naphthalene-l-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport layer ETL may include an electron transport material, such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In embodiments, a hole injection layer may be further disposed between the pixel electrode 180 and the hole transport layer HTL. An electron injection layer may be further disposed between the counter electrode 190 and the electron transport layer ETL.

In embodiments, the light-emitting portion EL may include the emission layer EML including an organic light-emitting material capable of emitting blue light having a central wavelength in a range, e.g., from about 420 nm to about 480 nm.

As illustrated in FIG. 7B, the light-emitting portion EL may include multiple light-emitting structures ES1, ES2, and ES3. Each of the light-emitting structures ES1, ES2, and ES3 may include a hole transport layer, an emission layer, and an electron transport layer. In embodiments, the light-emitting device ED shown in FIG. 7B may be a tandem-structured light-emitting device capable of generating white light.

Charge generation layers CGL1 and CGL2 may be arranged between neighboring light-emitting structures ES1, ES2, and ES3. The charge generation layers CGL1 and CGL2 may include a p-type charge generation layer and/or an n-type charge generation layer. The first charge generation layer CGL1 may be positioned between the first light-emitting structure ES1 and the second light-emitting structure ES2, and the second charge generation layer CGL2 may be positioned between the second light-emitting structure ES2 and the third light-emitting structure ES3.

In embodiments, the first light-emitting structure ES1, the first charge generation layer CGL1, the second light-emitting structure ES2, the second charge generation layer CGL2, the third light-emitting structure ES3, and the counter electrode 190 may be sequentially stacked on a top surface of the pixel electrode 180.

In embodiments, as illustrated in FIGS. 5 and 6, the light-emitting portion EL may be patterned in a selected light-emitting region defined by the pixel defining layer PDL. Accordingly, the light-emitting portions EL may be separated into island-like structures, spaced apart from each other in each of the multiple pixels.

In embodiments, the light-emitting portion EL may extend continuously across top surfaces of multiple pixels and the pixel defining layer PDL.

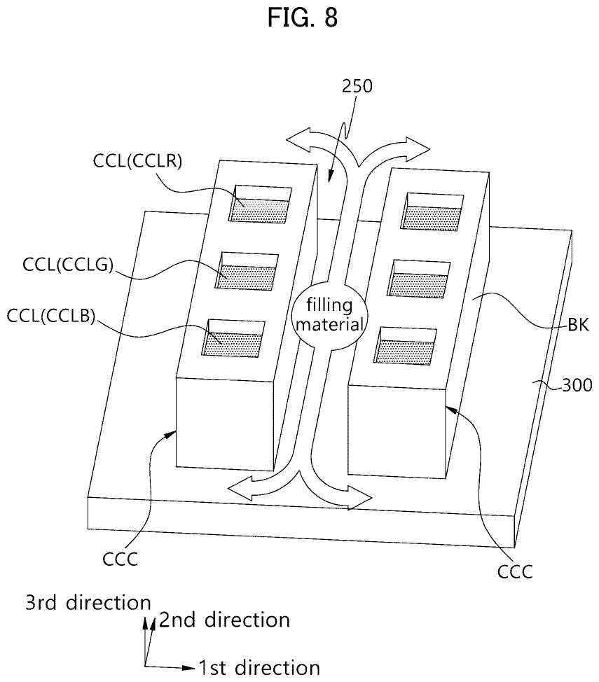

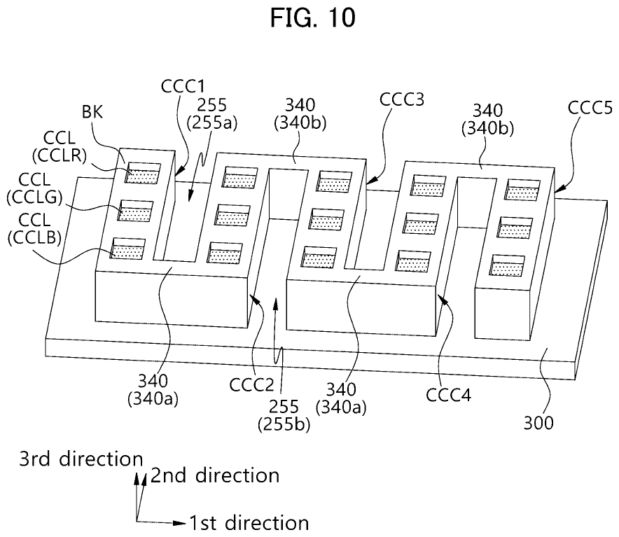

FIG. 8 is a schematic perspective view illustrating an upper structure of a display device in accordance with embodiments. For convenience of illustration, FIGS. 8 and 10 show color conversion layers corresponding to three pixels in each color conversion column; however, additional color conversion layers may be repeatedly arranged along the second direction. For example, a color conversion group, including the first color conversion layer CCLB, the second color conversion layer CCLG, and the third color conversion layer CCLR, may be repeatedly arranged in the second direction in the color control column.

For convenience of descriptions, the passivation layer 305, the capping layer 330, and other elements are omitted from FIGS. 8 to 10.

Referring to FIG. 8, as described with reference to FIGS. 4 and 6, the trench 250 may form or define a transparent area TA between the adjacent color conversion columns CCC in the first direction.

Both end portions of the trench 250 in the second direction may remain open. In embodiments, both end portions of the trench 250 in the second direction may not be blocked by the bank BK.

As illustrated in FIG. 8, a filling material used to laminate the upper structure US and the lower structure LS may be filled into the trench 250, and the filling material may be dispersed through the both end portions of the trench 250. This may prevent concentration and aggregation of the filling material, that otherwise occur at a connection portion in the case where a connected portion of the bank BK is present at the both end portions of the trench 250.

Further, light scattering caused by irregular refraction occurring in a region where the filling material agglomerates, as well as optical disturbances and image quality degradation resulting from the irregular refraction, may be prevented. Accordingly, a desired transmittance in the transparent area TA may be reliably achieved, and image quality degradation in the pixel area PXA due to optical disturbances may be avoided.

The color conversion columns CCC may be physically spaced apart from each other and separated from each other along the first direction, where they are repeatedly arranged. The trenches 250 may also be repeatedly arranged along the first direction, with both ends open between adjacent color conversion columns CCC.

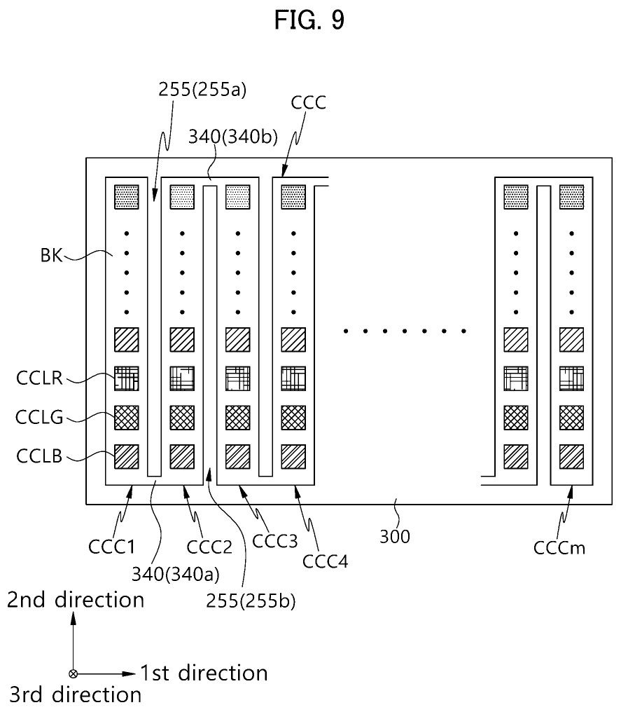

FIGS. 9 and 10 are a schematic plan view and a schematic perspective view, respectively, illustrating an upper structure of a display device in accordance with embodiments.

Referring to FIGS. 9 and 10, a first end portion of both first and second end portions of the trench 255 in the second direction between the color conversion columns CCC may be open, while a second end portion may be blocked.

The color conversion columns CCC neighboring or adjacent to each other in the first direction may be connected by a column connection portion 340. In embodiments, a pair of color conversion columns CCC separated by the trench 255 interposed therebetween may be connected to each other by the column connection portion 340. The column connection portion 340 may include substantially the same material as the bank BK and may be integrally formed as part of the bank BK.

For example, the number of m color conversion columns CCC, ranging from a first color conversion column CCC1 to an m^{th} color conversion column CCCm, may be arranged along the first direction. The number of (m−1) trenches 255 may be sequentially repeated between the color conversion columns CCC along the first direction.

First end portion(s) in the second direction of the first color conversion column CCC1 and a second color conversion column CCC2, which are adjacent to each other, may be connected by a first column connection portion 340a. Second portion(s) in the second direction of the second color conversion column CCC2 and a third color conversion column CCC3, which are adjacent to each other, may be connected by a second column connection portion 340b.

As described above, the first column connection portion 340a, connected to first end portions of the color conversion column CCC, and the second column connection portion 340b, connected to second end portions of the color conversion column CCC, may be alternately arranged along the first direction to connect the color conversion columns CCC to each other. Accordingly, the color conversion columns CCC may be connected to each other in a zigzag pattern along the first direction in a plan view.

Thus, even with the formation of the trenches 255 that define the transparent area TA, the bank BK may remain securely attached to the upper substrate 300, thereby ensuring sufficient mechanical stability and reliability.

The first end portion of the first trench 255a may be blocked by the first column connection portion 340a, while second end portion may remain open. Similarly, the first end portion of the second trench 255b may be open, while the second end portion may be blocked by the second column connection portion 340b.

The first trench 255a and the second trench 255b may be alternately and repeatedly arranged along the first direction to form or define the transparent area TA. The open end portions of the trench 255 may improve spreading property of the filling material and prevent optical disturbances caused by aggregation of the filling material. The blocked end portions of the trench 255 may maintain physical and mechanical stability of the bank BK and the color conversion column CCC.

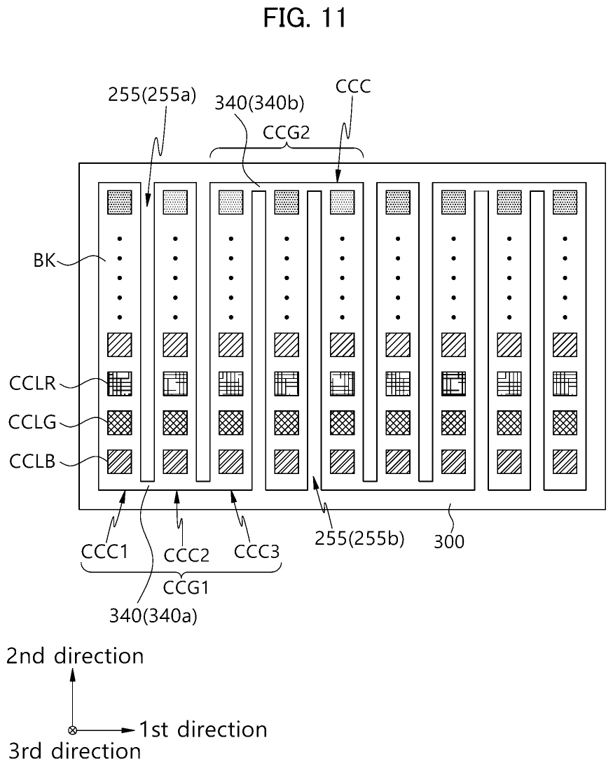

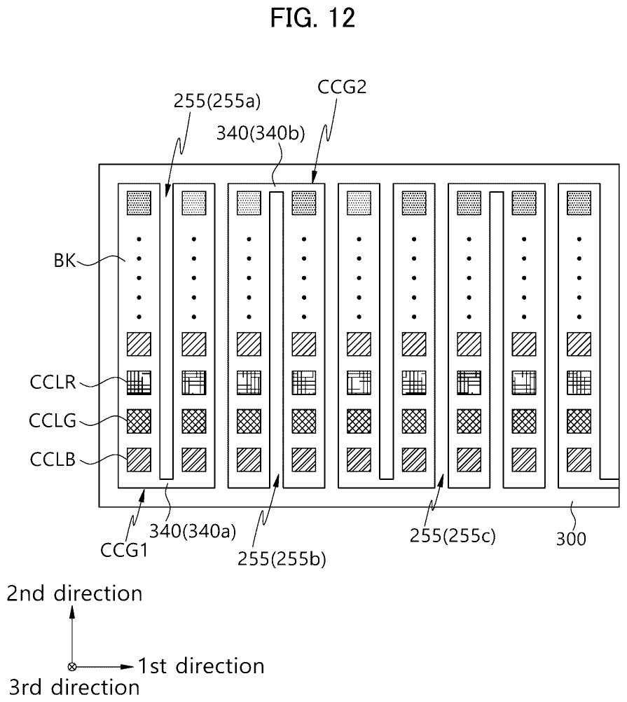

FIGS. 11 and 12 are schematic plan views illustrating an upper structure of a display device in accordance with embodiments.

Referring to FIG. 11, two or more color conversion columns CCC may be connected by a column connection portion 340.

In an embodiment, end portions of the first color conversion column CCC1, the second color conversion column CCC2, and the third color conversion column CCC3 may be connected by the first column connection portion 340a to form a first color conversion column group CCG1. Similarly, second end portions of three consecutive color conversion columns CCC, starting from the third color conversion column CCC3, may be connected by the second column connection portion 340b to form a second color conversion column group CCG2.

As described above, the first color conversion column group CCG1 and the second color conversion column group CCG2 may be alternately repeated along the first direction. The first color conversion column group CCG1 and the second color conversion column group CCG2, which are adjacent to each other, may share a central color conversion column CCC (e.g., the third color conversion column CCC3 shown in FIG. 11).

In the first color conversion column group CCG1, the transparent area TA may be formed in two or more first trenches 255a with first end portions blocked. In the second color conversion column group CCG2, the transparent area TA may be formed in two or more second trenches 255b with second end portions blocked.

The number of the color conversion columns CCC included in the first color conversion column group CCG1 and the second color conversion column group CCG2 may be adjusted in consideration of detachment prevention and physical stability of the bank BK. For example, the number of the color conversion columns CCC included in the first color conversion column group CCG1 and the second color conversion column group CCG2 may be adjusted to two, as illustrated in FIGS. 9 and 10, three, as illustrated in FIG. 11, or four or more.

Referring to FIG. 12, the trench 255 may include a trench having first end portion blocked and another trench having both first and second end portions open.

In embodiments, the trench 255 may include a first trench 255a having first end portion blocked by the first column connection portion 340a, a second trench 255b having second end portion blocked by the second column connection portion 340b, and a third trench 255c having both first and second end portions open.

The upper structure US may include a first color conversion column group CCG1 including the first column connection portion 340a and a second color conversion column group CCG2 including the second column connection portion 340b. The first color conversion column group CCG1 and the second color conversion column group CCG2 may be physically separated or spaced apart by the third trench 255c.

In embodiments, the first color conversion column group CCG1 and the second color conversion column group CCG2 may be alternately and repeatedly arranged along the first direction, with the third trench 255c interposed therebetween. In an embodiment, a selected number of the first color conversion column groups CCG1 may be consecutively arranged, with the third trench 255c interposed therebetween. Similarly, a selected number of the second color conversion column groups CCG2 may be consecutively arranged, with the third trench 255c interposed therebetween.

The third trench 255c may be disposed between the color conversion column groups to further increase dispersibility of the filling material and prevent aggregation or agglomeration of the filling material. Stability of the color conversion column groups CCG may be achieved while promoting diffusion of the filling material through the first trench 255a or the second trench 255b.

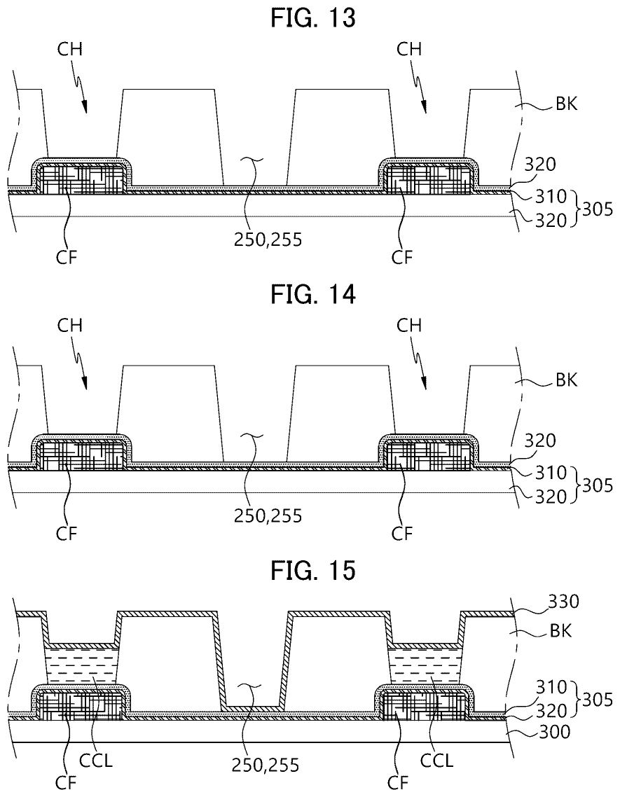

FIGS. 13 to 17 are schematic cross-sectional views illustrating a method of manufacturing a display device according to embodiments. For descriptive convenience, repeated descriptions of materials and structures described with reference to FIGS. 1 to 12 are omitted.

Referring to FIG. 13, the color filter CF may be formed on a device surface (an opposite surface or a bottom surface of the outer surface 300a) of the upper substrate 300, and the passivation layer 305 may be formed.

A color filter layer, including a colorant such as a dye and/or pigment, and a photosensitive binder resin, may be formed. The patterned color filters CFs for each pixel may be formed through exposure and development processes. In an embodiment, the color filter CF may be directly formed on the device surface of the upper substrate 300.

As described above, the passivation layer 305 may include a first passivation layer 310 and a second passivation layer 320.

In embodiments, the first passivation layer 310 may be formed using a coating process, such as a spin coating, a slit coating, a spray coating, or the like, with a composition including low refractive porous inorganic particles. As described above, the second passivation layer 320 may be formed using a low refractive inorganic material. The second passivation layer 310 may be formed through a deposition process, such as chemical vapor deposition (CVD) process, a sputtering process, a thermal deposition process, or the like.

Referring to FIG. 14, the bank BK may be formed on the device surface of the upper substrate 300 on which the color filter CF is formed.

In embodiments, a bank layer including a photosensitive polymer may be formed on the passivation layer 305 to cover the color filters CF. The bank layer may be partially removed using a photo-lithography process to form color conversion holes CH and trenches 250 and 255.

The color conversion hole CH may overlap the color filter CF included in each pixel. A portion of the passivation layer 305 formed on a top surface of the color filter CF may be exposed through the color conversion hole CH.

In an embodiment, as illustrated in FIGS. 4 and 6, the trench 250 having both end portions open may be formed. In an embodiment, as illustrated in FIGS. 9 to 11, the trench 255 with one end portion of both end portions blocked may be formed.

The color conversion hole CH and the trenches 250 and 255 may be formed together using the same photo-lithography process. For example, the color conversion hole CH and the trenches 250 and 255 may be formed simultaneously through a single photo-lithography process.

Referring to FIG. 15, the color conversion layer CCL filling each color conversion hole CH may be formed. Accordingly, the color conversion columns CCC, which include the bank BK and the color conversion layers CCL and are spaced apart from each other by the trenches 250 and 255, may be defined.

For example, a color conversion composition containing quantum dots and a binder resin may be filled or deposited into each color conversion hole CH using a printing process, such as an inkjet printing process, and cured to form the color conversion layer CCL.

As illustrated in FIG. 15, the color conversion layer CCL may partially fill the color conversion hole CH.

The capping layer 330 may be formed along surfaces of the bank BK, top surfaces of the color conversion layers CCL, and sidewalls and bottom surfaces of the trenches 250 and 255.

In embodiments, the capping layer 330 may be formed using a deposition process and may include an inorganic insulating material, such as silicon oxide, silicon nitride, or aluminum oxide, and/or an organic insulating material.

The upper structure US may be obtained through the processes described above with reference to FIGS. 13 to 15.

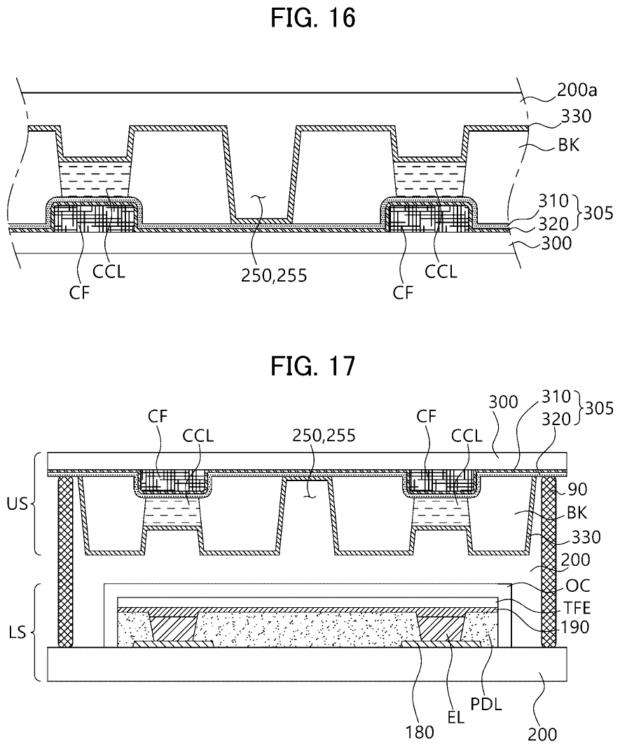

Referring to FIG. 16, a preliminary filler layer 200a may be formed to fill the trenches 250 and 255.

In embodiments, a filling material (e.g., a photopolymerizable composition) including an acrylate-based monomer and/or an epoxy-based monomer may be injected into the trenches 250 and 255. The filling material may extend over a top surface of the color conversion column CCC while sufficiently filling the trenches 250 and 255.

As illustrated in FIG. 8, the filling material may be diffused through the open end portions of the trenches 250 and 255. This diffusion may prevent aggregation or agglomeration of the filling material occurring at an end portion of the bank BK.

Referring to FIG. 17, the upper structure US and the lower structure LS may be combined or laminated using the preliminary filler layer 200a and a sealant 90.

The preliminary filler layer 200a may be further photocured while performing the lamination and may be converted into the filler layer 200, which includes, for example, an acrylic resin and/or an epoxy resin, to fix the upper structure US and the lower structure LS.

In embodiments, the filling material may be injected into the trenches 250 and 255 while the upper structure US and the lower structure LS are preliminarily coupled using the sealant 90. The filling material may be diffused through the open end portions of the trenches 250 and 255 to fill a space between the upper structure US and the lower structure LS. The filler layer 200 may be formed through a photocuring process.

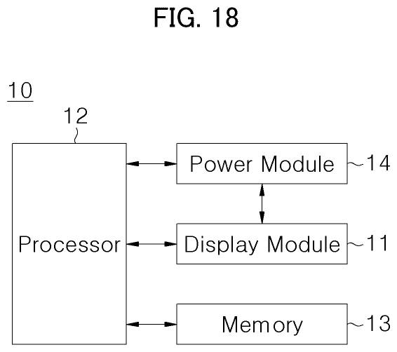

FIG. 18 is a schematic block diagram of an electronic device in accordance with an embodiment.

Referring to FIG. 18, an electronic device 10 according to an embodiment may include a display module 11, a processor 12, a memory 13, and a power module 14.

The processor 12 may include a central processing unit (CPU), an application processor (AP), a graphics processing unit (GPU), a communication processor (CP), an image signal processor (ISP), and/or a controller.

Data information for an operation of the processor 12 or the display module 11 may be stored in the memory 13. In case that the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module that converts a power supplied by the power supply module into a power required for the operation of the electronic device 10.

At least one of components of the electronic device 10, as described above, may be included in the display device according to the embodiments. Some individual modules functionally included in a module may be included in the display device, while others are provided separately from the display device. For example, the display module 11 may include the display device, and the processor 12, the memory 13, and the power module 14 may be provided in the form of another device in the electronic device 10 different from the display device.

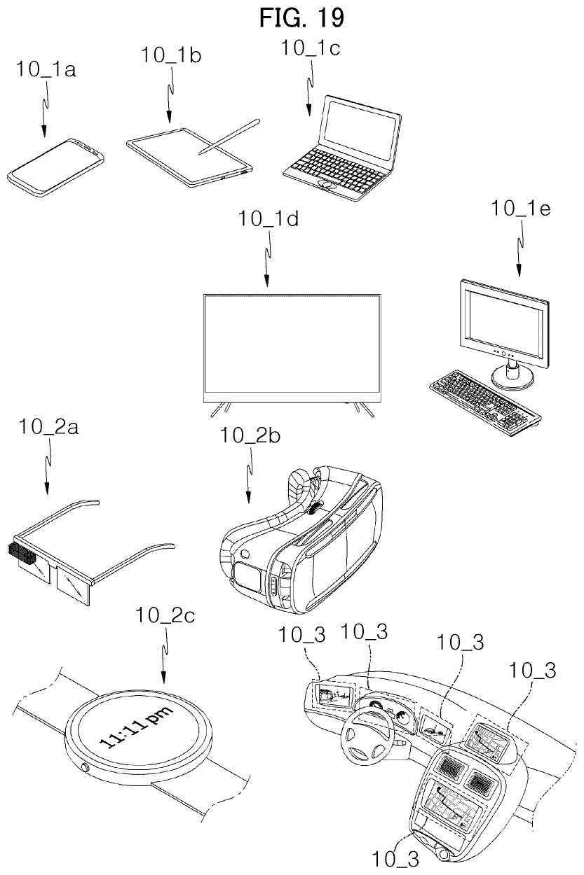

FIG. 19 is a schematic diagram of electronic devices in accordance with various embodiments.

Referring to FIG. 19, non-limiting examples of various electronic devices to which the display device according to the embodiments is applied include an electronic device for displaying an image such as a smartphone 10_1a, a tablet PC 10_1b, a laptop 10_1c, a TV 10_1d, a desk monitor 10_1e, and the like; a wearable electronic device including a display module such as smart glasses 10_2a, a head mounted display 10_2b, a smart watch 10_2c, and the like; a vehicle electronic device 10_3 including a display module such as a center information display (CID) disposed at a vehicle instrument panel, a center fascia, a dashboard, etc., a room mirror display, and the like. The electronic device may include virtual reality glasses or augmented reality glasses.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A display device, comprising:
a lower structure comprising light-emitting devices;
an upper structure combined with the lower structure and facing the lower structure, the upper structure comprising:
an upper substrate; and
color conversion columns on a surface of the upper substrate, each of the color conversion columns comprising a bank and color conversion layers in the bank, each of the color conversion layers corresponding to each of the light-emitting devices; and
a trench extending between the color conversion columns and having at least one open end portion.

2. The display device of claim 1, wherein the trench is defined by sidewalls of the bank included in a pair of neighboring color conversion columns, and
at least one end portion of the trench is unblocked by the bank.

3. The display device of claim 1, wherein end portions of the trench are open.

4. The display device of claim 3, wherein the color conversion columns are repeatedly arranged and physically separated from each other, with the trench interposed between the color conversion columns.

5. The display device of claim 1, wherein each of the trench and the color conversion columns has a first end portion and a second end portion in an extension direction of the color conversion columns, and
one of the first and second end portions of the trench is blocked and another one of the first and second end portions is open.

6. The display device of claim 5, wherein the trench comprises a first trench having the first end portion blocked and a second trench having the second end portion blocked.

7. The display device of claim 6, further comprising:
a first column connection portion that blocks the first end portion of the first trench and connects the first end portions of neighboring color conversion columns; and
a second column connection portion that blocks the second end portion of the second trench and connects the second end portions of the neighboring color conversion columns.

8. The display device of claim 7, wherein the first column connection portion and the second column connection portion are repeated alternately along a direction intersecting the extension direction of the color conversion columns.

9. The display device of claim 8, wherein the color conversion columns are connected to each other in a zigzag pattern.

10. The display device of claim 7, wherein the first column connection portion and the second column connection portion include a same material as the banks included in the neighboring color conversion columns, and are integrally connected to the banks.

11. The display device of claim 7, wherein three or more of the color conversion columns are connected by the first column connection portion to form a first color conversion column group, and
three or more of the color conversion columns are connected by the second column connection portion to form a second color conversion column group.

12. The display device of claim 11, wherein the first color conversion column group and the second color conversion column group are alternately repeated and share one color conversion column.

13. The display device of claim 1, wherein the trench comprises a trench in which only one of end portions in an extension direction of the color conversion columns is open, and a trench in which end portions in the extension direction of the color conversion columns are open.

14. The display device of claim 13, wherein the trench comprises a first trench having first end portion blocked in the extension direction of the color conversion columns, a second trench having second end portion blocked, and a third trench having first and second end portions open.

15. The display device of claim 1, further comprising a filler layer disposed between the upper structure and the lower structure to fill the trench.

16. A display device, comprising:
a lower structure comprising light-emitting devices; and
an upper structure combined with the lower structure and facing the lower structure, the upper structure comprising:
an upper substrate; and
color conversion columns on a surface of the upper substrate, each of the color conversion columns comprising a bank and color conversion layers in the bank, each of the color conversion layers corresponding to each of the light-emitting devices, wherein
the color conversion columns are repeatedly arranged at a specific interval along a first direction parallel to the surface, and each of the color conversion columns extends in a second direction parallel to the surface and intersecting the first direction, and
first end portions or second end portions in the second direction of neighboring color conversion columns are physically separated from each other in the first direction.

17. The display device of claim 16, further comprising a first column connection portion that connects first end portions of neighboring color conversion columns and a second column connection portion that connects second end portions of the neighboring color conversion columns.

18. A method of manufacturing a display device, the method comprising:
forming a bank layer on a surface of an upper substrate;
partially removing the bank layer to form a trench having at least one open end portion and color conversion holes surrounded by the bank layer;
forming color conversion layers in the color conversion holes;
filling the trench with a filling material, which diffuses into the open end portion of the trench; and
combining a lower structure comprising light-emitting devices with the upper substrate, on which the bank layer and the color conversion layers are formed, using the filling material.

19. The method of claim 18, further comprising, before forming the bank layer:
forming color filters on a surface of the upper substrate; and
forming a passivation layer along the surface of the upper substrate and the surfaces of the color filters, wherein
the color conversion holes expose portions of the passivation layer formed on top surfaces of the color filters.

20. An electronic device, comprising:
the display device of claim 1;
a memory; and
a processor that executes data included in the memory to control an operation of the display device.
